(19) United States
(12) Patent Application Publication
(10) Pub. No.: US 2013/0115756 A1
(43) Pub. Date: May 9, 2013

(54) PROCESSING METHOD FOR SEMICONDUCTOR WAFER HAVING PASSIVATION FILM ON THE FRONT SIDE THEREOF

(71) Applicant: Disco Corporation, Tokyo (JP)

(72) Inventor: Kazuma SEKIYA, Tokyo (JP)

(73) Assignee: DISCO CORPORATION, Tokyo (JP)

(21) Appl. No.: 13/663,035

(22) Filed: Oct. 29, 2012

(30) Foreign Application Priority Data
Nov. 8, 2011 (JP) 2011-244520

(51) Int. Cl. H01L 21/78

(52) U.S. Cl. 438/463; 257/E21.599

(57) ABSTRACT

A semiconductor wafer processing method forms a plurality of wafer dividing grooves respectively along a plurality of crossing streets formed on the front side of a semiconductor substrate of a semiconductor wafer to thereby partition a plurality of regions where a plurality of devices are respectively formed. The semiconductor wafer has a passivation film formed on the front side of the semiconductor substrate so as to cover the devices and the streets. A first laser beam is applied to the passivation film along each street to thereby form a film dividing groove in the passivation film along each street. A second laser beam is applied to the semiconductor substrate along the film dividing groove formed in the passivation film, thereby forming the wafer dividing groove in the semiconductor substrate along each street.

### BACKGROUND OF THE INVENTION

1. Field of the Invention

The present invention relates to a semiconductor wafer processing method for forming a plurality of wafer dividing grooves respectively along a plurality of crossing streets formed on the front side of a semiconductor substrate of a semiconductor wafer to thereby partition a plurality of regions where a plurality of devices are respectively formed, the semiconductor wafer having a passivation film formed on the front side of the semiconductor substrate so as to cover the devices and the streets.

2. Description of the Related Art

As well known in the art, in a semiconductor device fabrication process, a plurality of crossing streets are formed on the front side of a semiconductor substrate of silicon or the like constituting a semiconductor wafer to thereby partition a plurality of regions where a plurality of devices such as ICs and LSIs are respectively formed. The semiconductor wafer is divided along the streets to thereby obtain the individual devices. As a method of dividing a wafer such as a semiconductor wafer along the streets formed on the wafer, there has been proposed a method including the steps of applying a pulsed laser beam having an absorption wavelength to the wafer along each street to thereby form a wafer dividing groove along each street and next breaking the wafer along each street (see Japanese Patent Laid-open No. Hei 10-305420, for example).

### SUMMARY OF THE INVENTION

There has recently been put into practical use a semiconductor wafer having a protective film called a passivation film on the front side thereof for the purpose of protecting the devices such as ICs and LSIs. The passivation film is formed on the front side of a semiconductor substrate constituting the semiconductor wafer so as to cover the devices and the streets. The passivation film is formed of oxide such as SiO₂, SiF, SiON, and SiO (SixOy). When a laser beam having an absorption wavelength (e.g., 355 nm) to the semiconductor substrate, the energy of the laser beam absorbed by the semiconductor substrate reaches a bandgap energy to break the atomic bond in the semiconductor substrate, thereby performing the ablation. However, in the case that the passivation film of oxide such as SiO₂, SiF, SiON, and SiO (SixOy) is formed on the front side of the semiconductor substrate, there is a problem such that the energy of the laser beam may be diffused and reflected to hinder the performance of the ablation. Further, there is another problem such that the laser beam passed through the passivation film may ablate the semiconductor substrate to break the passivation film from the inside surface thereof.

It is therefore an object of the present invention to provide a semiconductor wafer processing method which can form a wafer dividing groove along each street of a semiconductor wafer having a passivation film on the front side thereof as suppressing the diffusion and reflection of the energy of the laser beam.

In accordance with an aspect of the present invention, there is provided a semiconductor wafer processing method for forming a plurality of wafer dividing grooves respectively along a plurality of crossing streets formed on the front side of a semiconductor substrate of a semiconductor wafer to thereby partition a plurality of regions where a plurality of devices are respectively formed, the semiconductor wafer having a passivation film formed on the front side of the semiconductor substrate so as to cover the devices and the streets, the semiconductor wafer processing method including a film dividing groove forming step of applying a first laser beam having an absorption wavelength to the passivation film along each street to thereby form a film dividing groove in the passivation film along each street; and a wafer dividing groove forming step of applying a second laser beam having an absorption wavelength to the semiconductor substrate along the film dividing groove formed in the passivation film after performing the film dividing groove forming step, thereby forming the wafer dividing groove in the semiconductor substrate along each street.

Preferably, the semiconductor substrate is formed of silicon, and the passivation film is formed of silicon dioxide. In this case, the wavelength of the first laser beam to be applied in the film dividing groove forming step is set to 532 nm, and the wavelength of the second laser beam to be applied in the wafer dividing groove forming step is set to 355 nm.

As described above, the semiconductor wafer processing method according to the present invention includes the film dividing groove forming step of applying the first laser beam having an absorption wavelength to the passivation film formed on the front side of the semiconductor substrate along each street to thereby form the film dividing groove in the passivation film along each street and the wafer dividing groove forming step of applying the second laser beam having an absorption wavelength to the semiconductor substrate along the film dividing groove formed in the passivation film after performing the film dividing groove forming step, thereby forming the wafer dividing groove in the semiconductor substrate along each street. Accordingly, there is no possibility that the energy of the laser beam may be diffused and reflected by the passivation film in performing the wafer dividing groove forming step to apply the laser beam having an absorption wavelength to the semiconductor substrate.

As a result, it is possible to solve the problem that the performance of the ablation may be hindered by the diffusion and reflection of the energy of the laser beam due to the passivation film. Further, in performing the wafer dividing groove forming step to apply the laser beam having an absorption wavelength to the semiconductor substrate, the passivation film has already been divided by the film dividing groove. Accordingly, it is also possible to solve the problem that the laser beam passed through the passivation film may ablate the semiconductor substrate to break the passivation film from the inside surface thereof.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWING

FIG. 1A is a perspective view of a semiconductor wafer to be processed by the semiconductor wafer processing method according to the present invention;

FIG. 1B is an enlarged sectional view of an essential part of the semiconductor wafer shown in FIG. 1A;

FIG. 2 is a perspective view showing a condition where the back side of the semiconductor wafer shown in FIG. 1A is attached to a protective tape supported to an annular frame;

FIG. 3 is a perspective view of a laser processing apparatus for performing the semiconductor wafer processing method according to the present invention;

FIG. 4 is a block diagram showing the configuration of first laser beam applying means included in the laser processing apparatus shown in FIG. 3;

FIG. 5 is a block diagram showing the configuration of second laser beam applying means included in the laser processing apparatus shown in FIG. 3;

FIG. 6A is a side view for illustrating a film dividing groove forming step in the semiconductor wafer processing method according to the present invention;

FIG. 6B is an enlarged sectional view of an essential part of the semiconductor wafer processed by the film dividing groove forming step;

FIG. 7A is a side view for illustrating a wafer dividing groove forming step in the semiconductor wafer processing method according to the present invention;

FIG. 7B is an enlarged sectional view of an essential part of the semiconductor wafer processed by the wafer dividing groove forming step;

FIG. 8A is a side view showing a condition where the film dividing groove forming step along one street on the semiconductor wafer is ended; and

FIG. 8B is a side view showing a condition where the wafer dividing groove forming step following the film dividing groove forming step shown in FIG. 8A is ended.

### DETAILED DESCRIPTION OF THE PREFERRED EMBODIMENT

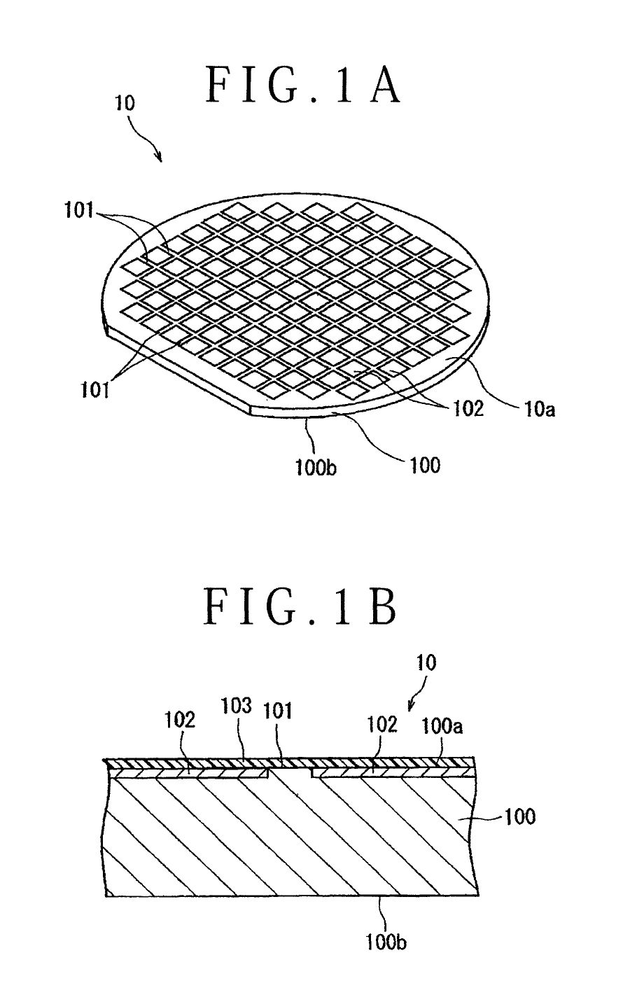

A preferred embodiment of the semiconductor wafer processing method according to the present invention will now be described in detail with reference to the drawings. FIG. 1A is a perspective view of a semiconductor wafer 10 as a workpiece, and FIG. 1B is an enlarged sectional view of an essential part of the semiconductor wafer 10 shown in FIG. 1A. The semiconductor wafer 10 shown in FIGS. 1A and 1B is formed from a semiconductor substrate 100 of silicon. A plurality of crossing streets 101 are formed on the front side 100a of the semiconductor substrate 100 to thereby partition a plurality of regions where a plurality of devices 102 such as ICs and LSIs are respectively formed. As shown in FIG. 1B, a passivation film 103 of silicon dioxide (SiO₂) is formed on the front side 100a of the semiconductor substrate 100 of the semiconductor wafer 10 so as to fully cover the devices 102 and the streets 101 for the purpose of protecting each device 102. In the present invention, the passivation film is formed of oxide such as SiO₂, SiF, SiON, and SiO (SixOy).

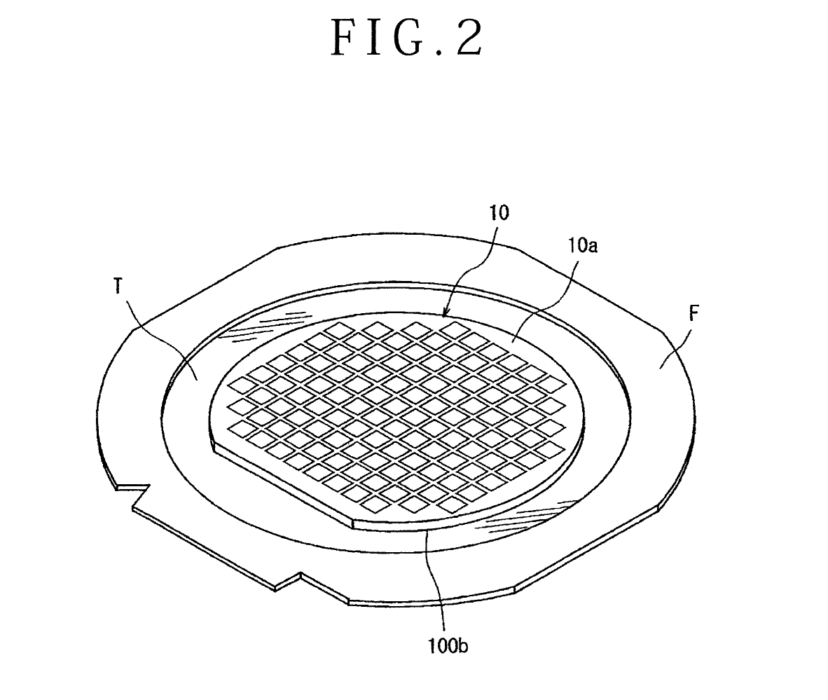

As shown in FIG. 2, the semiconductor wafer 10 is attached to a protective tape T supported to an annular frame F in the condition where the back side 100b of the semiconductor substrate 100 comes into contact with the protective tape T. The protective tape T is formed from a synthetic resin sheet such as a polyolefin sheet. Accordingly, the semiconductor wafer 10 is attached to the protective tape T supported to the annular frame F in the condition where the front side 10a of the semiconductor wafer 10, i.e., the front side 10a of the passivation film 103 formed on the front side 100a of the semiconductor substrate 100 is oriented upward. There will now be described a semiconductor wafer processing method for forming a wafer dividing groove along each street 101 on the semiconductor wafer 10 attached to the protective tape T supported to the annular frame F.

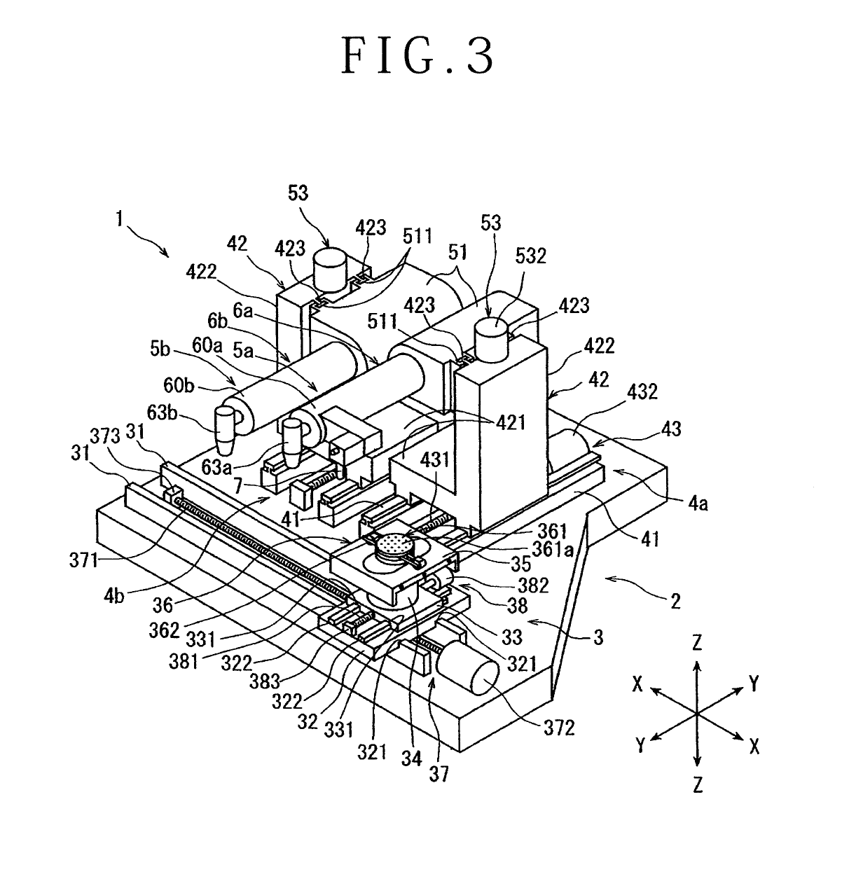

FIG. 3 is a perspective view of a laser processing apparatus 1 for performing the semiconductor wafer processing method according to the present invention. The laser processing apparatus 1 shown in FIG. 3 includes a stationary base 2, a chuck table mechanism 3 for holding a workpiece, the chuck table mechanism 3 being provided on the stationary base 2 so as to be movable in a feeding direction (X direction) shown by an arrow X, first and second laser beam applying unit supporting mechanisms 4a and 4b provided on the stationary base 2 so as to be movable in an indexing direction (Y direction) shown by an arrow Y perpendicular to the X direction, and first and second laser beam applying units 5a and 5b respectively provided on the first and second laser beam applying unit supporting mechanisms 4a and 4b so as to be movable in a focal position adjusting direction (Z direction) shown by an arrow Z.

The chuck table mechanism 3 includes a pair of guide rails 31 provided on the stationary base 2 so as to extend parallel to each other in the X direction, a first slide block 32 provided on the guide rails 31 so as to be movable in the X direction, a second slide block 33 provided on the first slide block 32 so as to be movable in the Y direction, a cover 35 supported by a cylindrical member 34 standing on the second slide block 33, and a chuck table 36 as workpiece holding means. The chuck table 36 has a vacuum chuck 361 formed of a porous material. A workpiece such as a wafer is adapted to be held under suction on the upper surface (workpiece holding surface) 361a of the vacuum chuck 361 by operating suction means (not shown). The chuck table 36 is rotatable by a pulse motor (not shown) provided in the cylindrical member 34. Further, the chuck table 36 is provided with clamps 362 for fixing an annular frame to be hereinafter described.

The lower surface of the first slide block 32 is formed with a pair of guided grooves 321 for slidably engaging the pair of guide rails 31 mentioned above. A pair of guide rails 322 are provided on the upper surface of the first slide block 32 so as to extend parallel to each other in the Y direction. Accordingly, the first slide block 32 is movable in the X direction along the guide rails 31 by the slidable engagement of the guided grooves 321 with the guide rails 31. The chuck table mechanism 3 further includes feeding means 37 for moving the first slide block 32 in the X direction along the guide rails 31. The feeding means 37 includes an externally threaded rod 371 extending parallel to the guide rails 31 so as to be interposed therebetween and a pulse motor 372 as a drive source for rotationally driving the externally threaded rod 371. The externally threaded rod 371 is rotatably supported at one end thereof to a bearing block 373 fixed to the stationary base 2 and is connected at the other end to the output shaft of the pulse motor 372 so as to receive the torque thereof. The externally threaded rod 371 is engaged with a tapped through hole formed in an internally threaded block (not shown) projecting from the lower surface of the first slide block 32 at a central portion thereof. Accordingly, the first slide block 32 is moved in the X direction along the guide rails 31 by operating the pulse motor 372 to normally or reversely rotate the externally threaded rod 371.

The lower surface of the second slide block 33 is formed with a pair of guided grooves 331 for slidably engaging the pair of guide rails 322 provided on the upper surface of the first slide block 32 as mentioned above. Accordingly, the second slide block 33 is movable in the Y direction along the guide rails 322 by the slidable engagement of the guided grooves 331 with the guide rails 322. The chuck table mechanism 3 further includes first indexing means 38 for moving the second slide block 33 in the Y direction along the guide rails 322. The first indexing means 38 includes an externally threaded rod 381 extending parallel to the guide rails 322 so as to be interposed therebetween and a pulse motor 382 as a drive source for rotationally driving the externally threaded rod 381. The externally threaded rod 381 is rotatably supported at one end thereof to a bearing block 383 fixed to the upper surface of the first slide block 32 and is connected at the other end to the output shaft of the pulse motor 382 so as to receive the torque thereof. The externally threaded rod 381 is engaged with a tapped through hole formed in an internally threaded block (not shown) projecting from the lower surface of the second slide block 33 at a central portion thereof. Accordingly, the second slide block 33 is moved in the Y direction along the guide rails 322 by operating the pulse motor 382 to normally or reversely rotate the externally threaded rod 381.

The first laser beam applying unit supporting mechanism 4a includes a pair of guide rails 41 provided on the stationary base 2 so as to extend parallel to each other in the Y direction and a movable support base 42 provided on the guide rails 41 so as to be movable in the Y direction. The movable support base 42 is composed of a horizontal portion 421 slidably supported to the guide rails 41 and a vertical portion 422 extending vertically upward from the upper surface of the horizontal portion 421. Further, a pair of guide rails 423 are provided on one side surface of the vertical portion 422 so as to extend parallel to each other in the Z direction, i.e., in the direction perpendicular to the workpiece holding surface 361a of the chuck table 36. The first laser beam applying unit supporting mechanism 4a further includes second indexing means 43 for moving the movable support base 42 in the Y direction along the guide rails 41. The second indexing means 43 includes an externally threaded rod 431 extending parallel to the guide rails 41 so as to be interposed therebetween and a pulse motor 432 as a drive source for rotationally driving the externally threaded rod 431. The externally threaded rod 431 is rotatably supported at one end thereof to a bearing block (not shown) fixed to the stationary base 2 and is connected at the other end to the output shaft of the pulse motor 432 so as to receive the torque thereof. The externally threaded rod 431 is engaged with a tapped through hole formed in an internally threaded block (not shown) projecting from the lower surface of the horizontal portion 421 at a central portion thereof. Accordingly, the movable support base 42 is moved in the Y direction along the guide rails 41 by operating the pulse motor 432 to normally or reversely rotate the externally threaded rod 431.

The first laser beam applying unit 5a includes a unit holder 51 and first laser beam applying means 6a mounted to the unit holder 51. The unit holder 51 is formed with a pair of guided grooves 511 for slidably engaging the pair of guide rails 423 provided on the vertical portion 422 of the movable support base 42. Accordingly, the unit holder 51 is supported to the movable support base 42 so as to be movable in the Z direction by the slidable engagement of the guided grooves 511 with the guide rails 423. The first laser beam applying unit 5a further includes focal position adjusting means 53 for moving the unit holder 51 along the guide rails 423 in the Z direction. The focal position adjusting means 53 includes an externally threaded rod (not shown) extending parallel to the guide rails 423 so as to be interposed therebetween and a pulse motor 532 as a drive source for rotationally driving this externally threaded rod. Accordingly, the unit holder 51 and the first laser beam applying means 6a are moved in the Z direction along the guide rails 423 by operating the pulse motor 532 to normally or reversely rotate this externally threaded rod.

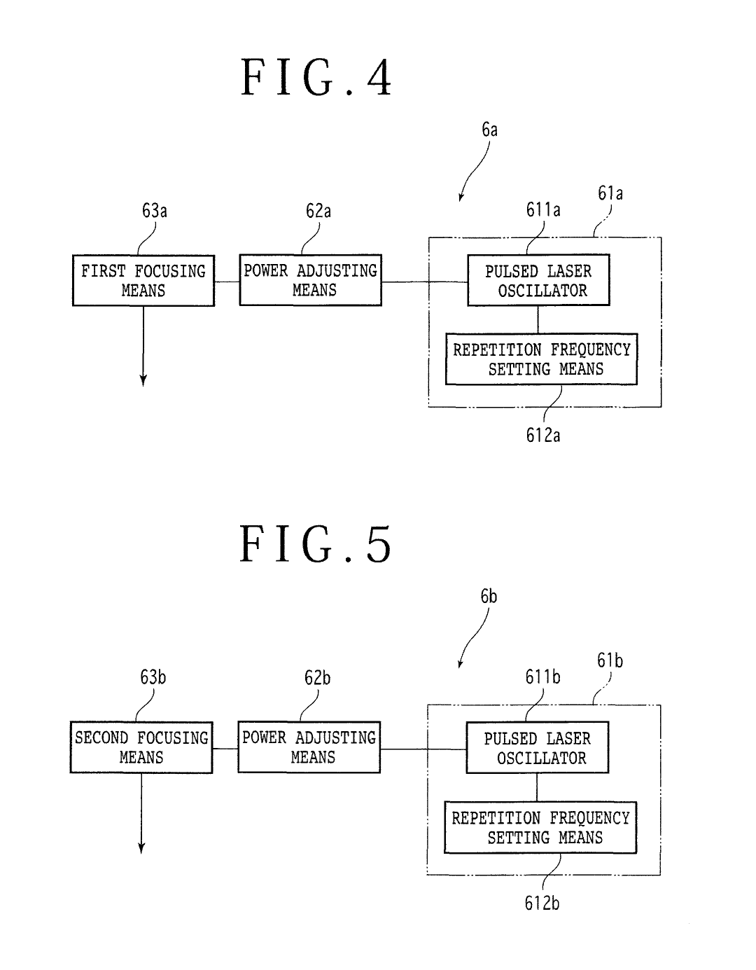

The first laser beam applying means 6a includes a cylindrical casing 60a fixed to the unit holder 51 so as to extend in a substantially horizontal direction. As shown in FIG. 4, the first laser beam applying means 6a includes pulsed laser beam oscillating means 61a provided in the casing 60a, power adjusting means 62a provided in the casing 60a, and first focusing means 63a mounted on the front end of the casing 60a. The pulsed laser beam oscillating means 61a is composed of a pulsed laser oscillator 611a such as a YAG laser oscillator or a YVO4 laser oscillator and repetition frequency setting means 612a connected to the pulsed laser oscillator 611a. The pulsed laser oscillator 611a of the pulsed laser oscillating means 61a functions to oscillate a pulsed laser beam having a wavelength of 532 nm. The power adjusting means 62a functions to adjust the power of the pulsed laser beam oscillated by the pulsed laser oscillating means 61a to a predetermined value.

Referring back to FIG. 3, imaging means 7 is provided at the front end portion of the casing 60a constituting the first laser beam applying means 6a. The imaging means 7 includes an ordinary imaging device (CCD) for imaging the workpiece by using visible light, infrared light applying means for applying infrared light to the workpiece, an optical system for capturing the infrared light applied to the workpiece by the infrared light applying means, and an imaging device (infrared CCD) for outputting an electrical signal corresponding to the infrared light captured by the optical system. An image signal output from the imaging means 7 is transmitted to control means (not shown).

The second laser beam applying unit supporting mechanism 4b and the second laser beam applying unit 5b will now be described. In the second laser beam applying unit supporting mechanism 4b and the second laser beam applying unit 5b, the components having substantially the same functions as those of the components of the first laser beam applying unit supporting mechanism 4a and the first laser beam applying unit 5a are denoted by the same reference numerals. The second laser beam applying unit supporting mechanism 4b is parallel to the first laser beam applying unit supporting mechanism 4a, and the movable support base 42 of the second laser beam applying unit supporting mechanism 4b is opposed to the movable support base 42 of the first laser beam applying unit supporting mechanism 4a so as to be symmetric with respect to a line. Accordingly, the second laser beam applying unit 5b provided on the vertical portion 422 of the second laser beam applying unit supporting mechanism 4b is close arranged in line symmetry to the first laser beam applying unit 5a provided on the vertical portion 422 of the movable support base 42 of the first laser beam applying unit supporting mechanism 4a. No imaging means is provided on second laser beam applying means 6b of the second laser beam applying unit 5b.

The second laser beam applying means 6b includes a cylindrical casing 60b fixed to the unit holder 51 so as to extend in a substantially horizontal direction. As shown in FIG. 5, the second laser beam applying means 6b includes pulsed laser beam oscillating means 61b provided in the casing 60b, power adjusting means 62b provided in the casing 60b, and second focusing means 63b mounted on the front end of the casing 60b. The pulsed laser beam oscillating means 61b is composed of a pulsed laser oscillator 611b such as a YAG laser oscillator or a YVO4 laser oscillator and repetition frequency setting means 612b connected to the pulsed laser oscillator 611b. The pulsed laser oscillator 611b of the pulsed laser beam oscillating means 61b functions to oscillate a pulsed laser beam having a wavelength of 355 nm. The power adjusting means 62b functions to adjust the power of the pulsed laser beam oscillated by the pulsed laser beam oscillating means 61b to a predetermined value. The second focusing means 63b of the second laser beam applying means 6b is spaced a predetermined distance in the X direction from the first focusing means 63a of the first laser beam applying means 6a.

The semiconductor wafer processing method using the laser processing apparatus 1 shown in FIG. 3 is performed in the following manner to form a wafer dividing groove along each street 101 on the semiconductor wafer 10 attached to the protective tape T supported to the annular frame F shown in FIG. 2. First, the semiconductor wafer 10 supported through the protective tape T to the annular frame F is placed on the chuck table 36 of the laser processing apparatus 1 in the condition where the protective tape T comes into contact with the upper surface of the chuck table 36. By operating the suction means (not shown), the semiconductor wafer 10 is held under suction on the chuck table 36 through the protective tape T. Further, the annular frame F is fixed by the clamps 362. Accordingly, the semiconductor wafer 10 is held under suction on the chuck table 36 through the protective tape T in the condition where the passivation film 103 formed on the front side 100a of the semiconductor substrate 100 is oriented upward.

Thereafter, the feeding means 37 is operated to move the chuck table 36 holding the semiconductor wafer 10 through the protective tape T to a position directly below the imaging means 7. When the chuck table 36 is positioned directly below the imaging means 7, an alignment operation is performed by the imaging means 7 and the control means (not shown) to detect a subject area of the semiconductor wafer 10 to be laser-processed. More specifically, the imaging means 7 and the control means perform image processing such as pattern matching for making the alignment of the streets 101 extending in a first direction on the semiconductor wafer 10 and the first focusing means 63a of the first laser beam applying means 6a for applying the laser beam along the streets 101, thus performing the alignment of a laser beam applying position. The imaging means 7 and the control means similarly perform the alignment operation for the other streets 101 extending in a second direction perpendicular to the first direction mentioned above on the semiconductor wafer 10. In performing the semiconductor wafer processing method of the present invention, the first focusing means 63a of the first laser beam applying means 6a and the second focusing means 63b of the second laser beam applying means 6b are aligned in the feeding direction (X direction).

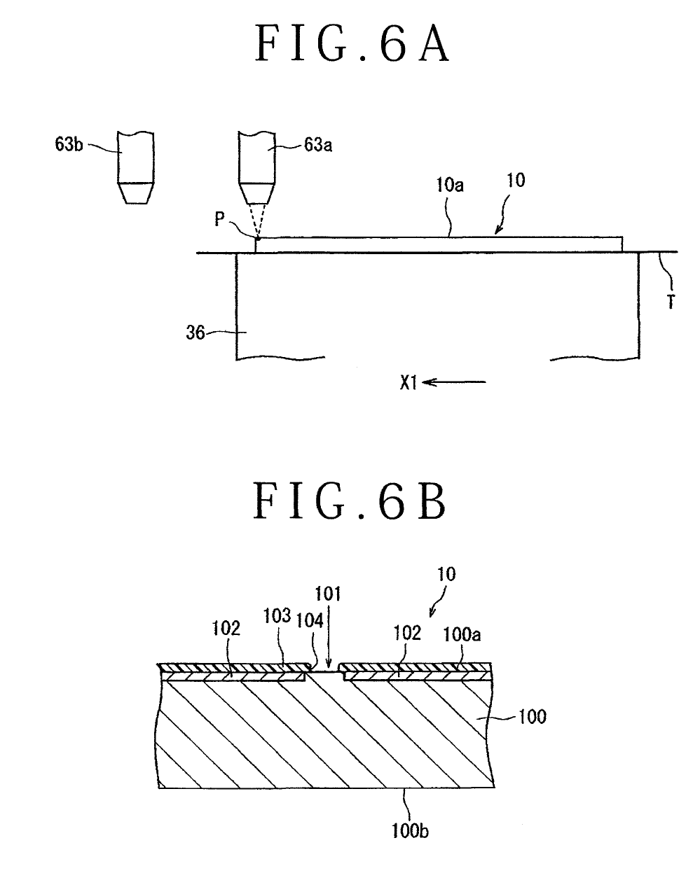

After performing the alignment operation to detect all of the streets 101 extending in the first and second directions on the semiconductor wafer 10 held on the chuck table 36, a film dividing groove forming step is performed in such a manner that the first laser beam applying means 6a is operated to apply a laser beam having an absorption wavelength to the passivation film 103 along each street 101, thereby forming a film dividing groove in the passivation film 103 along each street 101. As shown in FIG. 6A, the chuck table 36 is first moved to a laser beam applying area below the first focusing means 63a of the first laser beam applying means 6a. More specifically, one end (left end as viewed in FIG. 6A) of a predetermined one of the streets 101 extending in the first direction is positioned directly below the first focusing means 63a of the first laser beam applying means 6a as shown in FIG. 6A (a laser beam applying position where the laser beam from the first focusing means 63a is applied). In this condition, the focal position adjusting means 53 of the first laser beam applying means 6a is operated to set the focal point P of the pulsed laser beam to be applied from the first focusing means 63a near the front side 10a of the semiconductor wafer 10 as shown in FIG. 6A. Similarly, the focal position adjusting means 53 of the second laser beam applying means 6b is operated to set the focal point P of the pulsed laser beam to be applied from the second focusing means 63b near the front side 10a of the semiconductor wafer 10. Thereafter, the first laser beam applying means 6a is operated to apply a first pulsed laser beam having an absorption wavelength to the passivation film 103 from the first focusing means 63a to the semiconductor wafer 10. At the same time, the chuck table 36 is moved in the feeding direction shown by an arrow X1 in FIG. 6A at a predetermined feed speed (film dividing groove forming step). As a result, the passivation film 103 formed on the front side 100a of the semiconductor substrate 100 of the semiconductor wafer 10 is divided along the predetermined street 101 to form a film dividing groove 104 as shown in FIG. 6B.

For example, the film dividing groove forming step is performed under the following processing conditions.

Light source: YAG pulsed laser

Wavelength: 532 nm (second harmonic generation of YAG pulsed laser)

Repetition frequency: 50 kHz

Average power: 0.5 W

Focused spot diameter: 10 μm

Work feed speed: 100 mm/s

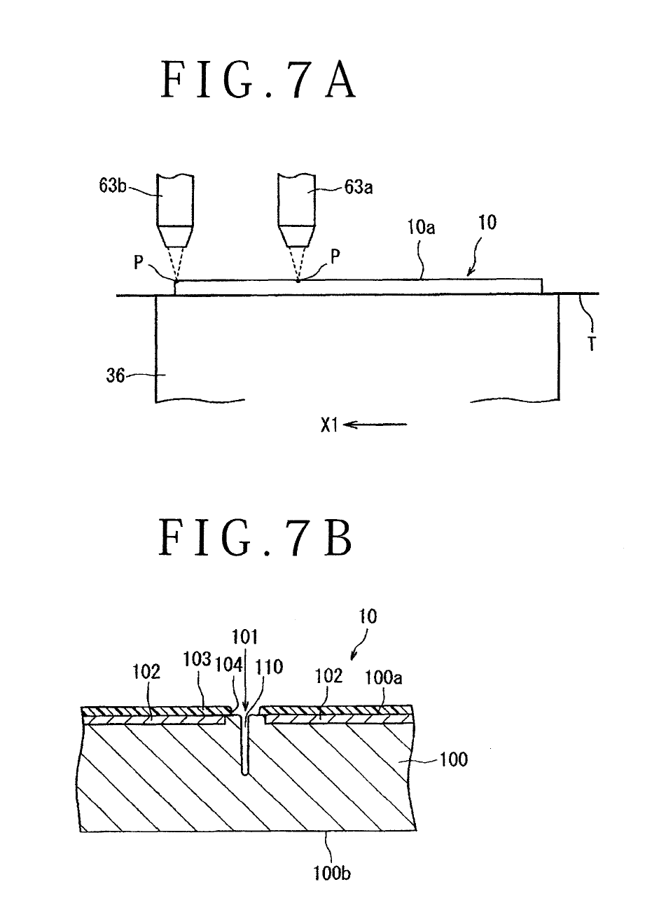

When one end of the predetermined street 101 reaches a position directly below the second focusing means 63b of the second laser beam applying means 6b as shown in FIG. 7A after forming the film dividing groove 104 in the passivation film 103 along the predetermined street 101, the second laser beam applying means 6b is operated to apply a second pulsed laser beam having an absorption wavelength to the semiconductor substrate 100 from the second focusing means 63b to the semiconductor wafer 10. At the same time, the chuck table 36 continues to be moved in the feeding direction shown by an arrow X1 in FIG. 7A at the predetermined feed speed (wafer dividing groove forming step). As a result, the second pulsed laser beam is applied through the film dividing groove 104 formed in the passivation film 103 along the predetermined street 101 to the semiconductor substrate 100 of the semiconductor wafer 10, thereby forming a wafer dividing groove 110 in the semiconductor substrate 100 of the semiconductor wafer 10 along the film dividing groove 104 formed in the passivation film 103 along the predetermined street 101 as shown in FIG. 7B.

For example, the wafer dividing groove forming step is performed under the following processing conditions.

Light source: YAG pulsed laser

Wavelength: 355 nm (third harmonic generation of YAG pulsed laser)

Repetition frequency: 50 kHz

Average power: 3 W

Focused spot diameter: 1 μm

Work feed speed: 100 mm/s

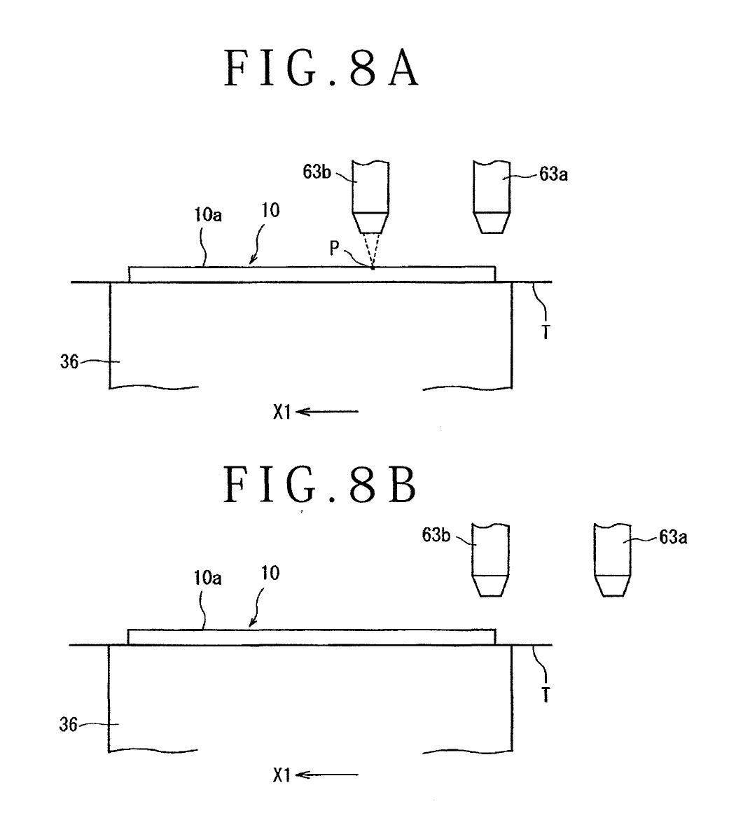

When the other end (right end as viewed in FIG. 8A) of the predetermined street 101 reaches the position directly below the first focusing means 63a of the first laser beam applying means 6a in performing the film dividing groove forming step and the wafer dividing groove forming step as shown in FIG. 8A, the operation of the first laser beam applying means 6a is stopped. Thereafter, the chuck table 36 is further moved in the feeding direction shown by an arrow X1 in FIG. 8A. When the other end (right end as viewed in FIG. 8A) of the predetermined street 101 reaches the position directly below the second focusing means 63b of the second laser beam applying means 6b as shown in FIG. 8B, the operation of the second laser beam applying means 6b is stopped and the movement of the chuck table 36 is also stopped.

The film dividing groove forming step and the wafer dividing groove forming step mentioned above are similarly performed along all of the streets 101 extending in the first direction. Thereafter, the chuck table 36 is rotated 90° to thereby 90° rotate the semiconductor wafer 10 held on the chuck table 36. In this condition, the film dividing groove forming step and the wafer dividing groove forming step are similarly performed along all of the other streets 101 extending in the second direction perpendicular to the first direction.

After thus performing the film dividing groove forming step and the wafer dividing groove forming step along all of the streets 101 extending in the first and second directions on the semiconductor wafer 10, the semiconductor wafer 10 is subjected to a dividing step as the next step.

As described above, the semiconductor wafer processing method according to the present invention includes the film dividing groove forming step of applying the first laser beam having an absorption wavelength to the passivation film 103 formed on the front side 100a of the semiconductor substrate 100 along each street 101 to thereby form the film dividing groove 104 in the passivation film 103 along each street 101 and the wafer dividing groove forming step of applying the second laser beam having an absorption wavelength to the semiconductor substrate 100 along the film dividing groove 104 formed in the passivation film 103 after performing the film dividing groove forming step, thereby forming the wafer dividing groove 110 in the semiconductor substrate 100 along each street 101. Accordingly, there is no possibility that the energy of the laser beam may be diffused and reflected by the passivation film 103 in performing the wafer dividing groove forming step to apply the laser beam having an absorption wavelength to the semiconductor substrate 100. As a result, it is possible to solve the problem that the performance of the ablation may be hindered by the diffusion and reflection of the energy of the laser beam due to the passivation film. Further, in performing the wafer dividing groove forming step to apply the laser beam having an absorption wavelength to the semiconductor substrate 100, the passivation film 103 has already been divided by the film dividing groove 104. Accordingly, it is also possible to solve the problem that the laser beam passed through the passivation film may ablate the semiconductor substrate to break the passivation film from the inside surface thereof.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A semiconductor wafer processing method for forming a plurality of wafer dividing grooves respectively along a plurality of crossing streets formed on a front side of a semiconductor substrate of a semiconductor wafer to thereby partition a plurality of regions where a plurality of devices are respectively formed, said semiconductor wafer having a passivation film formed on the front side of said semiconductor substrate so as to cover said devices and said streets, said semiconductor wafer processing method comprising:
a film dividing groove forming step of applying a first laser beam having an absorption wavelength to said passivation film along each street to thereby form a film dividing groove in said passivation film along each street; and
a wafer dividing groove forming step of applying a second laser beam having an absorption wavelength to said semiconductor substrate along said film dividing groove formed in said passivation film after performing said film dividing groove forming step, thereby forming said wafer dividing groove in said semiconductor substrate along each street.

2. The semiconductor wafer processing method according to claim 1, wherein said semiconductor substrate is formed of silicon, and said passivation film is formed of silicon dioxide.

3. The semiconductor wafer processing method according to claim 2, wherein the wavelength of said first laser beam to be applied in said film dividing groove forming step is set to 532 nm, and the wavelength of said second laser beam to be applied in said wafer dividing groove forming step is set to 355 nm.
